(19) United States
(12) Patent Application Publication
(10) Pub. No.: US 2019/0304905 A1
(43) Pub. Date: Oct. 3, 2019

(54) CO-PLACEMENT OF RESISTOR AND OTHER DEVICES TO IMPROVE AREA & PERFORMANCE

(71) Applicant: QUALCOMM Incorporated, San Diego, CA (US)

(72) Inventors: Tin Tin WEE, San Diego, CA (US); Alvin Leng Sun LOKE, San Diego, CA (US); Jacob SCHNEIDER, San Diego, CA (US)

(21) Appl. No.: 15/992,473

(22) Filed: May 30, 2018

Related U.S. Application Data
(60) Provisional application No. 62/649,110, filed on Mar. 28, 2018.

(51) Int. Cl. H01L 23/522; H01L 23/528; H01L 27/02; H01L 49/02; H01L 27/06

(52) U.S. Cl. CPC H01L 23/5228; H01L 23/528; H01L 23/5226; H01L 27/0255; G05F 1/46; H01L 28/20; H01L 28/60; H01L 27/0647; H01L 23/5223

(57) ABSTRACT

Co-placement of resistor and other devices to improve area and performance is disclosed. In one implementation, a semiconductor circuit includes a resistor residing on a back end of line (BEOL) resistor layer, a plurality of interlevel metal vias coupling the BEOL resistor layer to one or more metal layers underneath the BEOL resistor layer, and a diode residing on a silicon substrate underneath the one or more metal layers, wherein a planar surface of the diode and a planar surface of the resistor at least partially overlap with each other, and the diode and the resistor are coupled to each other through the plurality of interlevel metal vias.

### CLAIM OF PRIORITY UNDER 35 U.S.C. § 119

The present application for patent claims priority to Provisional Application No. 62/649,110 entitled “Co-placement of resistor and other devices to improve area and performance” filed Mar. 28, 2018, and assigned to the assignee hereof and hereby expressly incorporated by reference herein.

### FIELD OF DISCLOSURE

Aspects of the present disclosure relate generally to semiconductor circuit layout, and more particularly to co-placement of resistors and other devices to reduce layout area and improve circuit performance.

### BACKGROUND

A semiconductor die may include many semiconductor devices (e.g., transistors). The semiconductor devices may be interconnected by one or more metal layers to form integrated circuits. As the dimensions of devices scale down, routing and placement congestion on a die increases, making it more difficult to route and place devices on the die while keeping the layout as compact as possible.

### SUMMARY OF THE DISCLOSURE

The following presents a simplified summary of one or more implementations to provide a basic understanding of such implementations. This summary is not an extensive overview of all contemplated implementations and is intended to neither identify key or critical elements of all implementations nor delineate the scope of any or all implementations. The sole purpose of this summary is to present some concepts of one or more implementations in a simplified form as a prelude to the more detailed description that is presented later.

In one implementation, a semiconductor circuit includes a resistor residing on a back end of line (BEOL) resistor layer, a plurality of multi-level metal wires and interlevel metal vias coupling the BEOL resistor layer to one or more metal layers underneath the BEOL resistor layer, and a diode residing on a silicon substrate underneath the one or more metal layers, wherein a planar surface of the diode and a planar surface of the resistor at least partially overlap with each other, and the diode and the resistor are coupled to each other through the plurality of multi-level metal wires and interlevel metal vias.

In some implementations, the diode is configured as part of an electrostatic discharge (ESD) protection structure. Further, the ESD protection structure can be incorporated into an output driver of a transmitter. In an alternative implementation, the resistor and the diode are configured as part of a bandgap reference circuit.

In some implementations, a semiconductor circuit includes a resistor residing on a back end of line (BEOL) resistor layer, and a capacitor underneath the BEOL resistor layer, wherein the resistor and the capacitor are arranged in a physical stack. The capacitor can include two sets of fingers or two plates, a first one of which residing on a first metal layer and a second one of which residing on a second metal layer. Both the first and the second metal layers are located between the BEOL resistor layer and a silicon substrate. The semiconductor circuit can further include routing to couple the resistor to the capacitor, wherein the at least a portion of the routing extends in a direction substantially normal to a planar surface of the silicon substrate. In some implementations, the resistor and the capacitor are connected to each other in series between an output of a low drop-out regulator (LDO) and ground.

In some implementations, an input/output (I/O) includes an output driver having a resistor residing on a back end of line (BEOL) resistor layer, and an electrostatic discharge (ESD) protection circuit having a diode residing on a silicon substrate underneath the BEOL resistor layer, wherein the resistor and the diode are arranged in a physical stack. The I/O can further include routing to couple the resistor to the diode, wherein at least a portion of the routing extends in a direction substantially normal to a planar surface of the silicon substrate.

To the accomplishment of the foregoing and related ends, the one or more implementations include the features hereinafter fully described and particularly pointed out in the claims. The following description and the annexed drawings set forth in detail certain illustrative aspects of the one or more implementations. These aspects are indicative, however, of but a few of the various ways in which the principles of various implementations may be employed and the description implementations are intended to include all such aspects and their equivalents.

### BRIEF DESCRIPTION OF THE DRAWINGS

FIG. 1 is a cross-section view of a conventional semiconductor die.

FIG. 2 is a cross-section view of one implementation of a semiconductor die having a stacked resistor-diode structure.

FIG. 3A shows one example of an output driver of a transmitter with an electrostatic discharge (ESD) protection circuit.

FIG. 3B shows a top view of the layout 330 of output driver 300 in FIG. 3A.

FIG. 3C shows one implementation of a layout of output driver 300 in FIG. 3A for a process that supports fabricating resistors on BEOL layer.

FIG. 4A shows one exemplary bandgap reference circuit.

FIG. 4B shows an exemplary layout 430 of the bandgap reference circuit 400 in FIG. 4A.

FIG. 4C shows one implementation of a top view of a layout of bandgap reference circuit 400 for a process that supports fabricating resistors on BEOL layer.

FIG. 5A shows an exemplary low drop out regulator (LDO) with a RC compensation network coupled to an output of the LDO.

FIG. 5B shows exemplary layout of LDO circuit 500 for a conventional process that does not support building resistors on a BEOL layer.

FIG. 5C shows one implementation of a layout of LDO circuit 500 for an advance process that supports building resistors on a BEOL layer.

### DETAILED DESCRIPTION

The detailed description set forth below, in connection with the appended drawings, is intended as a description of various configurations and is not intended to represent the only configurations in which the concepts described herein may be practiced. The detailed description includes specific details to providing a thorough understanding of the various concepts. However, it will be apparent to those skilled in the art that these concepts may be practiced without these specific details. In some instances, well-known structures and components are shown in block diagram form to avoid obscuring such concepts.

Starting at foundry 28 nm complementary metal oxide semiconductor (CMOS) node, High-K Gate Dielectric and Metal Gate (HKMG) replaced the nitrided-oxide/polysilicon gate stack system to allow continued gate dielectric capacitance (Cox) scaling without incurring severe gate tunneling leakage current penalty and Cox reduction from polysilicon gate charge depletion. HKMG integration made continued support of the unsilicided polysilicon precision resistor extremely difficult, if not untenable. Replacement of the precision unsilicided poly resistor is a thin film Middle-Of-Line (MOL) precision resistors, which include refractory metal compounds, such as titanium nitride, inserted above the gate but beneath the interconnect stack (Metal-1 and above). With smaller feature sizes required in each new node, the topography introduced by the MOL resistors has been eroding into the depth of focus margin for critical low-level Back-End-Of-Line (BEOL) lithography, for instance, typically Metal-1 to Metal-3. Starting at 5 nm, some leading foundry has moved the MOL resistor module to above the critical BEOL modules, situating the new BEOL resistor between two BEOL metal layers, e.g., Metal-3 and Metal-4, since Metal-4 lithography modules are not as sensitive to depth of focus constraints. High placement of BEOL resistors allows opportunistic placement of transistors or other devices beneath the BEOL resistors.

In some implementations, certain devices can be strategically placed underneath the BEOL resistors, such as diodes, diode-connected PNP bipolar junction transistors (BJTs), and capacitors. Diodes and resistors typically occupy a lot of area, so significant area saving can be achieved by placing these two elements in a stack (or substantially overlapping each other) in the same area, especially in wireline transmitter drivers (e.g., double data rate (DDR), serializer-deserializer (SerDes), etc.), where electrostatic discharge (ESD) protection diodes can be opportunistically placed under the BEOL resistors. Unlike logic and certain memory devices (e.g., static random-access memory (SRAM) devices), BEOL resistors and diodes alone are not benefiting much from node-to-node scaling; resistor scaling requires thinning of the resistor layer which would otherwise introduce unacceptable variation in resistance. So, by stacking BEOL resistors and diodes in the same area, more compact floorplan of the design can be achieved. Such a physical stack of diodes and BEOL resistors also make shorter routing between them possible because the diodes and BEOL resistors are physically closer together and routing connecting the diodes and BEOL resistors do not have to go around guard ring, unlike in typical conventional designs. Shorter routing further provides the advantages of lower pin capacitance or input/output (I/O) capacitance, hence lower operating power as well as signal reflection (i.e., signal loss), which are key challenges in achieving higher speed in wireline transmitters.

Furthermore, the diode and BEOL resistor physical stack is particularly advantageous for electrostatic discharge (ESD) circuits, which are typically required in I/Os. ESD diodes generally do not consume any active current but only passes through reverse-bias leakage current, so self-heating of ESD diodes is insignificant. Thus, ESD diodes pose little reliability impact on overlying BEOL resistors. ESD diodes typically require very low-resistance metal connection from ESD diodes to the bumps. Since resistors are typically only connected at the ends using stacked vias, little metal resource is used for the resistor connections and most of metal resource remain available for the ESD diode-to-bump metal connection. The metallization used for the ESD diode-to-bump connection which surrounds the BEOL resistors can also serve as a heat sink to dissipate heat away from the BEOL resistors. Some examples are discussed in detail below to further illustrate the concept and the advantages thereof.

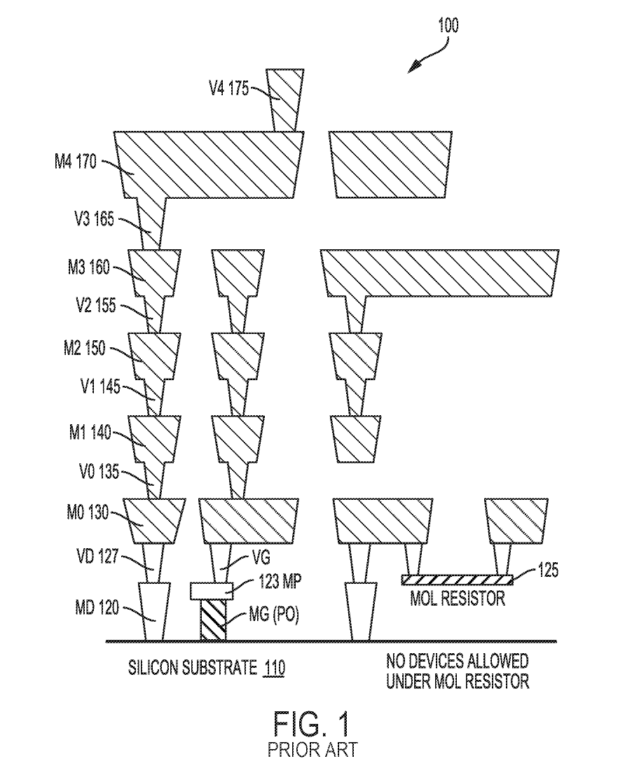

FIG. 1 is a cross-section view of a conventional semiconductor die 100. The semiconductor die 100 includes a silicon substrate 110, on which semiconductor devices, for example, transistors, diodes, etc. can be built. The silicon substrate 110 is typically provided in the form of a silicon wafer. The semiconductor die 100 can further include a metal contact layer MD 120 on silicon substrate 110, a gate contact layer MG 121 on silicon substrate 110, a second gate contact layer MP 123 on top of MG 121, a Middle-End-Of-Line (MOL) metal layer 125 above MD 120 and MP 123, vias 127 (e.g., VD, VG), metal zero (M0) layer 130, via zero (V0) 135, metal one (M1) layer 140, via one (V1) 145, metal two (M2) layer 150, via two (V2) 155, metal three (M3) layer 160, via three (V3) 165, and metal four (M4) layer 170, and via four (V4) 175. Metal layers 130, 140, 150, 160, 170 and vias 135, 145, 155, 165, 175 are arranged on top of vias 127 in the order set forth above.

In general, contact layers 120, 121, 123, MOL 125, metal layers 130, 140, 150, 160, 170 and vias 127, 135, 145, 155, 165, 175 are deposited and etched in a similar order, starting with contacts MD 120, MG 121, MP 123, MOL 125, and so forth. It should be noted that MOL 125 is deposited relatively early in the process of fabrication of semiconductor die 100. One typical component built on MOL 125 is resistor (a.k.a. MOL resistor). Since MOL 125 is relatively close to silicon substrate 110 and there is no metal layer and/or via between MOL 125 and silicon substrate 110, no devices can be built under MOL 125. As such, circuitry that include a MOL resistor and other semiconductor devices (e.g., diode) requires the MOL resistor and the other semiconductor devices be laid out lateral to each other (for instance, side-by-side) on the silicon wafer. For circuitry having an array of MOL resistors, significant area on the silicon wafer is required. To better illustrate the silicon area requirement imposed, an exemplary circuit is discussed in detail below.

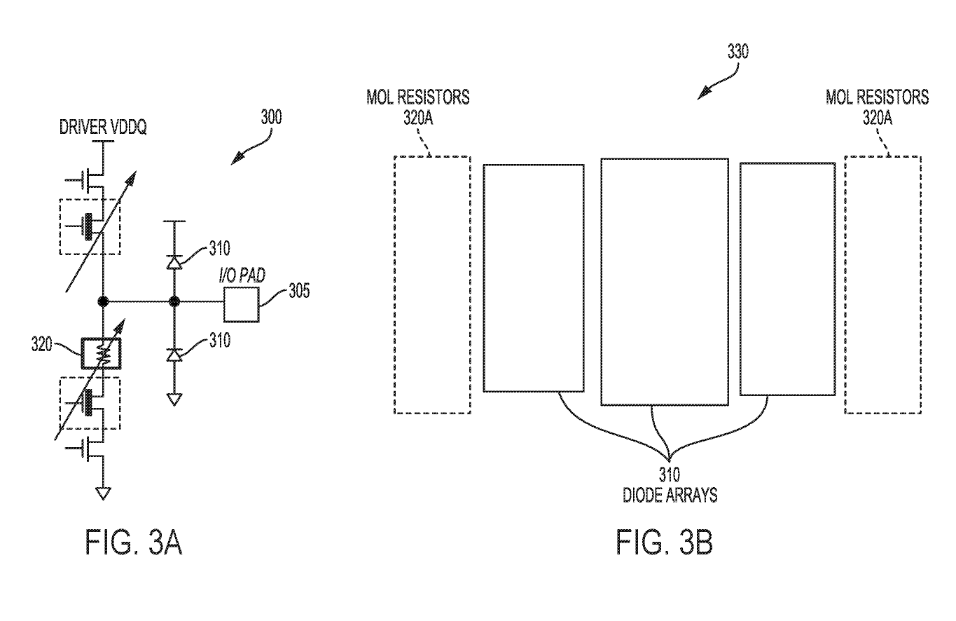

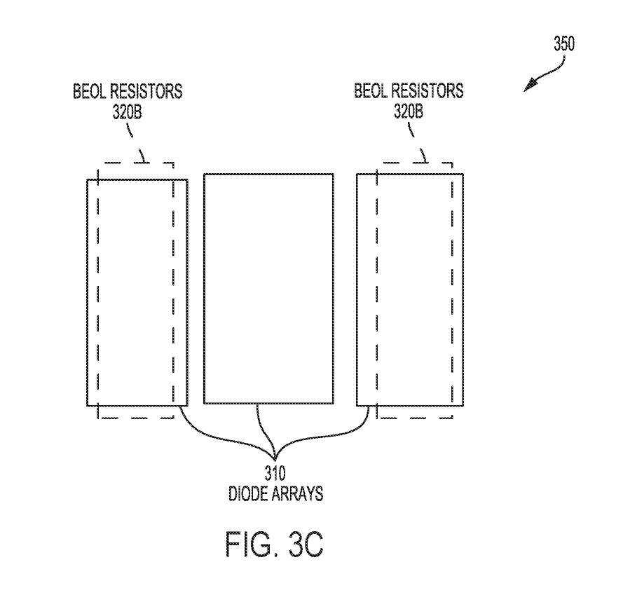

FIG. 3A shows one example of an output driver of a transmitter with an electrostatic discharge (ESD) protection circuit. Output driver 300 can be incorporated into a transmitter to drive output signals onto an input/output (I/O) pad 305. Output driver 300 in FIG. 3A includes a resistor 320. Resistor 320 is coupled to I/O pad 305 and a plurality of diodes 310 for ESD protection. An exemplary layout of output driver 300 is shown in FIG. 3B.

FIG. 3B shows a top view of the layout 330 of the ESD circuit 300. In layout 330, there are three (3) arrays of diodes 310 and two (2) arrays of MOL resistors 320A. One array of MOL resistors 320A is on the left side of the arrays of diodes 310 and the other array of MOL resistors 320A is on the right side of the arrays of diodes 310. As explained above, no devices can be built underneath MOL resistors 320A using conventional processes, the arrays of diodes 310 and the arrays of MOL resistors 320A, therefore, are laid out side-by-side, taking up a significant amount of silicon area.

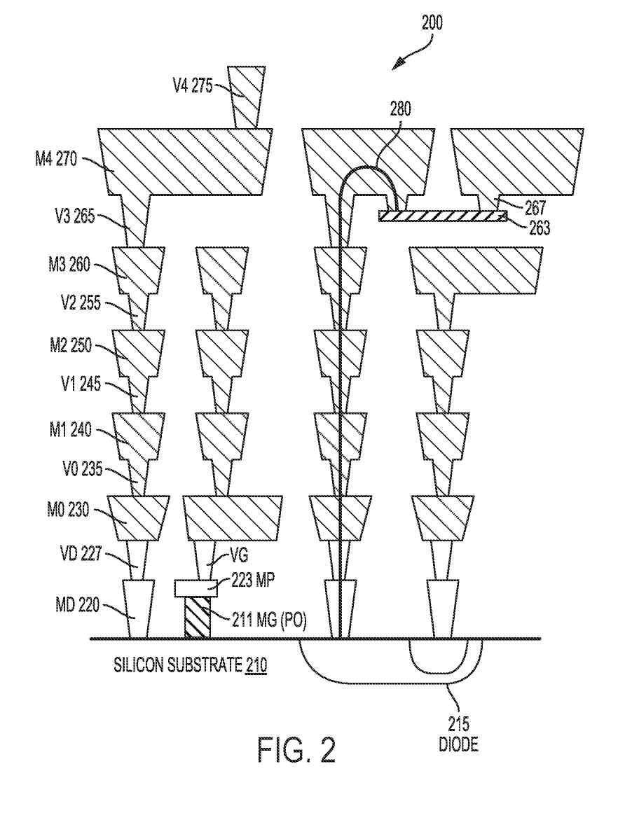

In more advance processes, resistors can be built between two metal layers that is deposited later in the fabrication process. Such metal layers are commonly referred to as back end of line (BEOL) metal layers. FIG. 2 shows a cross-section view of one implementation of a semiconductor die 200 having BEOL metal layers. The semiconductor die 200 includes a silicon substrate 210, on which semiconductor devices, for example, diode 215, transistors, etc., can be built. Silicon substrate 210 is typically provided in the form of a silicon wafer. The semiconductor die 200 can further include a metal contact layer MD 220 on silicon substrate 210, a gate contact layer MG 211 on silicon substrate 210, a second gate contact layer MP 223 on top of MG 211, vias 227 (e.g., diffusion via VD, gate via VG), metal zero (M0) layer 230, via zero (V0) 235, metal one (M1) layer 240, via one (V1) 245, metal two (M2) layer 250, via two (V2) 255, metal three (M3) layer 260, via three (V3) 265, and metal four (M4) layer 270, and via four (V4) 275. Metal layers 230, 240, 250, 260, 270 are deposited during back end of line process, and thus, are also referred to as BEOL metal layers. Note that each of V0 235, V1 245, V2 255, V3 265, and V4 275 couples one metal layer to another metal layer, and thus, can also be referred to as interlevel metal vias, as opposed to other types of vias. Specifically, in one implementation, V0 235 couples a top planar surface of M0 230 to a bottom planar surface of M1 240; V1 245 couples a top planar surface of M1 240 to a bottom planar surface of M2 250; V2 255 couples a top planar surface of M2 to a bottom planar surface of M3 260; V3 265 couples a top planar surface of M3 260 to a bottom planar surface of M4 270. The semiconductor die 200 further includes a BEOL resistor layer 263, on which resistors can be built. BEOL resistor layer 263 is located between two BEOL layers, such as M3 260 and M4 270 in the current example, and is substantially parallel to the BEOL metal layers (e.g., M4, M3, M2, M1, and M0). BEOL resistor layer 263 can comprise of a refractory metal compound such as titanium nitride (TiN). BEOL resistor layer 263 and resistors formed thereon can be coupled to M4 270 by via 267, which extends from a top planar surface of BEOL resistor layer 263 to the bottom planar surface of M4 270. M4 270 can be coupled to other metal layers underneath, directly or indirectly, through V3 265, V2 255, V1 245, and V0 235 as described above. It should be noted that there is no MOL layer in semiconductor die 200. As such, at least some resistors in circuits fabricated in semiconductor die 200 are formed in BEOL resistor layer 263, and such resistors can be referred to as BEOL resistors.

As shown in FIG. 2, there are multiple metal layers (e.g., M3 260, M2 250, M1 240, and M0 230) and interlevel metal vias (e.g., V2 255, V1 245, V0 235) underneath BEOL resistor layer 263. One should appreciate that other implementations may include fewer metal layers and fewer vias underneath BEOL resistor layer 263. It is possible to form a routing 280 from BEOL resistor layer 263 through the vias and metal layers underneath BEOL layer 265 to VD 227 and contact layers 220 and 223 such that resistors formed on BEOL resistor layer 263 can be electrically coupled to other components residing on silicon substrate 210, such as diode 215. As shown in FIG. 2, routing 280 can go through the various metal layers and interlevel metal vias to couple to silicon substrate 210 and components residing on silicon substrate (e.g., diode 215). In some implementations, routing 280 includes multi-level metal wires (e.g., wires formed on M4 270, M3 260, M2 250, M1 240, and/or M0 230) and interlevel metal vias (e.g., V3 265, V2 255, V1 245, and/or V0 235). As shown in FIG. 2, at least a portion of routing 280 extends in a direction substantially normal to a planar surface of the silicon substrate 210. Viewing from above the semiconductor die 200, the devices residing on the silicon substrate 210 can be directly, or at least partially, overlapping with the BEOL resistors. In other words, the BEOL resistors and the components or devices to which the BEOL resistors are electrically connected to can be arranged in a physical stack. Thus, the BEOL resistors and the components connected thereto form a three-dimensional physical stack structure on a single silicon wafer. Because the size of resistor arrays is typically quite large, placing other devices underneath the resistor arrays can provide significant area saving. Moreover, this physical stack arrangement does not require the use of multiple wafers and/or interposer; and hence, the arrangement shown in FIG. 2 is less costly compared to some conventional designs that use two or more silicon wafers and interposer. To further illustrate the area saving achieved, consider the exemplary output driver 300 in FIG. 3A. One implementation of a layout of the output driver 300 for a process that supports fabricating resistors on BEOL resistor layer is shown in FIG. 3C.

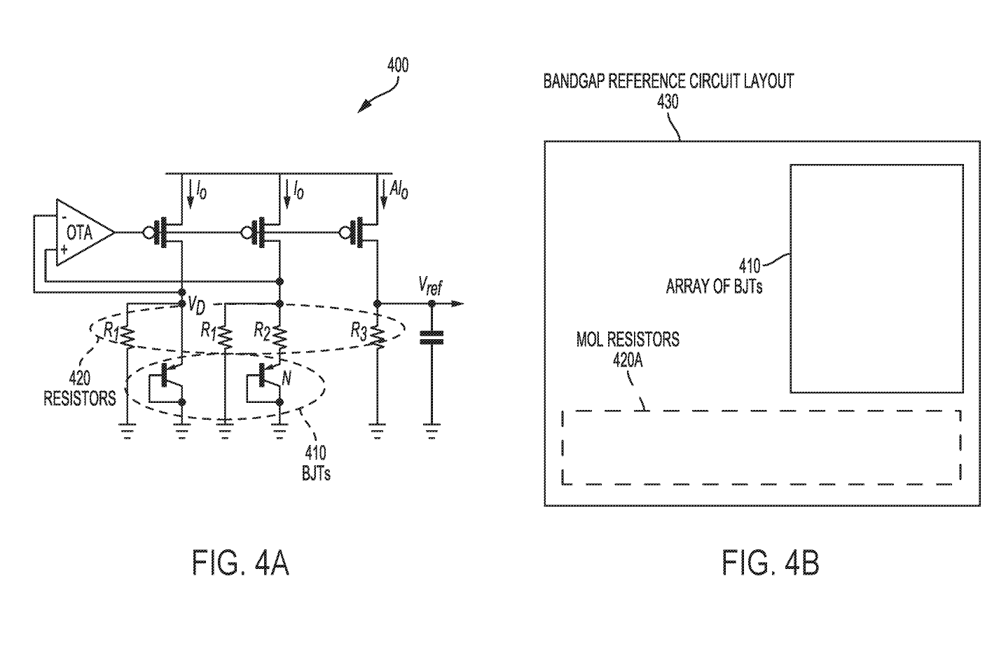

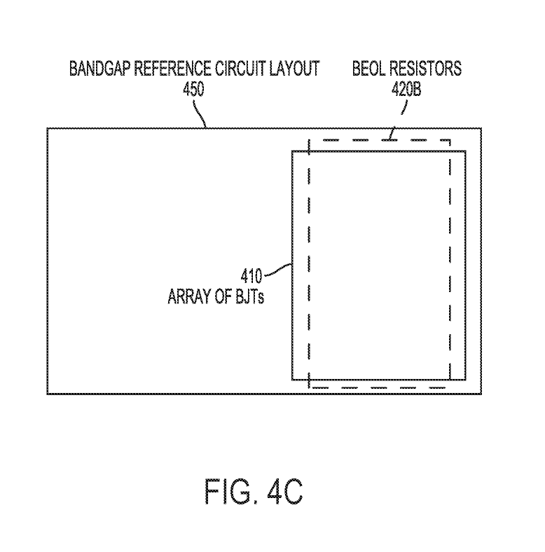

FIG. 3C shows one implementation of a layout of output driver 300 in FIG. 3A for a process that supports fabricating resistors on BEOL layer. The layout 350 includes three (3) arrays of diodes 310 and two (2) arrays of BEOL resistors 320B. One of the BEOL resistor arrays 320B substantially overlaps with one of the arrays of diodes 310 on the left, while the other one of the BEOL resistor arrays 320B substantially overlap with one of the arrays of diodes 310 on the right, thus forming a three-dimensional ESD structure monolithically. Note that the entire ESD structure is formed on a single wafer. There is no stacking of multiple wafers and interposer is not required to construct the ESD structure. In contrast to the layout for processes that do not support fabricating resistors on BEOL layer, such as layout 330 shown in FIG. 3B, the area occupied by layout 350 is significantly smaller than the area occupied by layout 330. In some implementations, the area saved can be about 8 μm². For output drivers that incorporate ESD circuit 300, the area saving on each bit can be summed up to 16 times (×16) double data rate physical interface (DDR PHY). Furthermore, as the BEOL resistor arrays 320 and the diode arrays 310 can be overlapped, some implementations of a driver incorporating the ESD layout 350 can be configured as substantially a square on silicon, thus providing interoperability of vertical or horizontal I/O pads. Another advantage of layout 350 is shorter routing between BEOL resistors 320B and diodes 310. Specifically, routing can go through the interlevel metal vias (e.g., V3 265, V2 255, V1 245, V0 235 in FIG. 2) and metal layers (e.g., M4 270, M3 260, M2 250, M1 240, M0 230 in FIG. 2) from BEOL resistor layer (e.g., BEOL resistor layer 263 in FIG. 2) to contact layers (e.g., MD 220, MP 223, and MG 221 in FIG. 2) to couple to the diodes 310 on silicon substrate (e.g., silicon substrate 210 in FIG. 2). Instead of extending the routing in a direction substantially parallel to a planar surface of silicon substrate, the routing in layout 350 can take the shorter path by extending in a direction substantially normal to the planar surface of silicon substrate through the various vias and metal layers. Furthermore, the routing in layout 350 does not have to go around guard rings (not shown) surrounding diodes 310, unlike the routing in layout 330 in FIG. 3B. In addition to output drivers, the concept of stacking BEOL resistors over other devices can be extended to other circuits to save area. Another example is provided below with reference to FIGS. 4A-4C.

FIG. 4A shows one exemplary bandgap reference circuit 400. The bandgap reference circuit 400 includes a plurality of resistors 420 and at least two diode-connected PNP bipolar junction transistors (BJTs) 410. Each of the BJTs 410 is coupled between ground and at least one of the resistors 420. One implementation of a top view of a layout of circuit 400 for a process that provides a MOL layer, but not a BEOL resistor layer, is shown in FIG. 4B. In FIG. 4B, an exemplary layout 430 of the bandgap reference circuit 400 in FIG. 4A is shown. Layout 430 includes an array of MOL resistors 420A and an array of BJTs 410. Because layout 430 is for a process that does not provide a BEOL layer, the resistors 420 in bandgap reference circuit 400 are implemented on the MOL layer, and thus, are referred to as “MOL resistors” 420A. The array of MOL resistors 420A is adjacent to the array of BJTs 410 and there is no overlapping between the two arrays because, as discussed above, no device is allowed underneath the MOL layer.

One implementation of a top view of a layout of bandgap reference circuit 400 for a process that provides a BEOL layer is shown in FIG. 4C. As shown in FIG. 4C, bandgap reference circuit layout 450 includes an array of BEOL resistors 420B and an array of BJTs 410. The array of BEOL resistors 420B substantially overlaps the array of BJTs 410, forming a stack. Like layout 350 of the ESD circuit 300 in FIG. 3C, layout 450 also achieves significant area saving by stacking BEOL resistors 420B over the array of BJTs 410, as opposed to layout 430 in FIG. 4B. In addition to area saving, layout 450 also achieves a lower capacitance in comparison to layout 430 in FIG. 4B because layout 450 is more compact. This can help improve analog performance metrics of bandgap reference circuit 400, such as power-supply rejection ratio (P SRR).

In some implementations, it is more advantageous to choose devices that tend to conduct low to moderate quiescent currents or not to switch too often to be placed underneath BEOL resistors to avoid overheating of semiconductor die. With BEOL resistors over a device, heat dissipation from the device can be compromised. Because diodes 320 of the ESD circuit 300 and the BJTs 410 of the bandgap reference circuit 400 tend to conduct very small quiescent currents, both diodes 320 and BJTs 410 are particularly suitable for being placed underneath BEOL resistors.

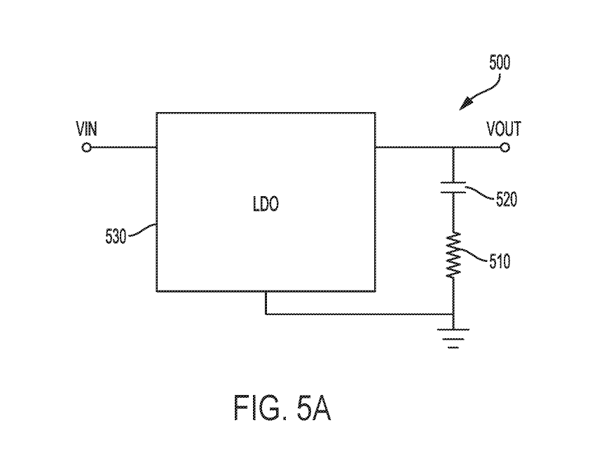

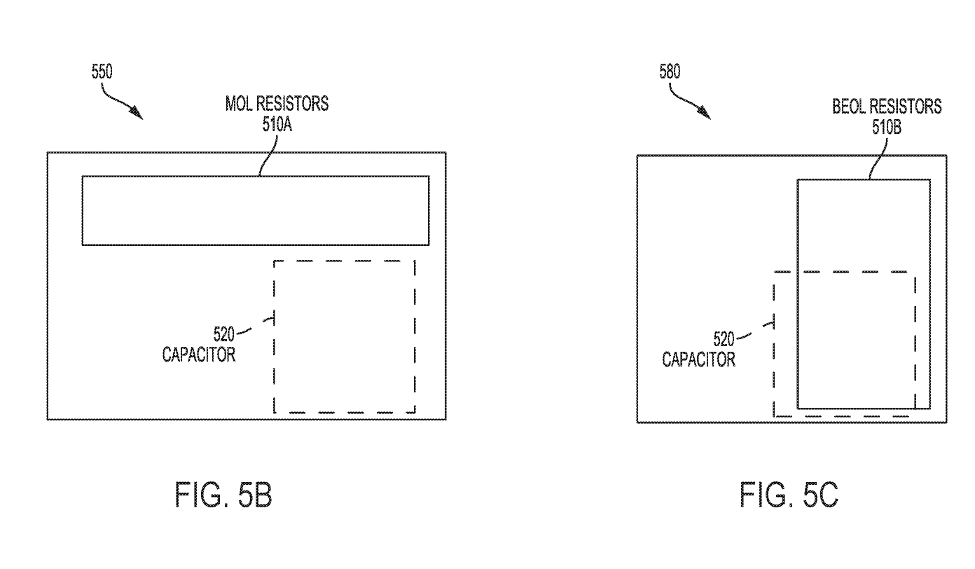

In addition to devices residing on silicon substrate, BEOL resistors can be strategically placed above components residing on metal layers underneath the BEOL layer. FIG. 5A shows an exemplary LDO with a RC compensation network coupled to an output of the LDO. Specifically, the LDO circuit 500 includes a LDO 530, a resistor 510, and a capacitor 520. LDO 530 has an input to receive Vin and an output Vout. Resistor 510 and capacitor 520 are coupled in series between the output of LDO 530 and ground to stabilize Vout, or in other words, to keep Vout relatively quiet.

An exemplary layout of LDO circuit 500 for a conventional process that does not support building resistors on a BEOL resistor layer is shown in FIG. 5B. As shown in FIG. 5B, layout 550 includes a MOL resistor 510A and a capacitor 520 corresponding to resistor 510 and capacitor 520 in FIG. 5A, respectively. MOL resistor 510A is fabricated on the MOL layer underneath the first metal layer (typically referred to as M0), and hence, no other components can be placed underneath MOL resistor 510A. Therefore, capacitor 520 is placed adjacent to MOL resistor 510A, where capacitor 520 and MOL resistor 510A do not overlap each other.

FIG. 5C shows one implementation of a layout of LDO circuit 500 for an advance process that supports building resistors on a BEOL layer. Layout 580 has a LDO 530, a BEOL resistor 510B, and a capacitor 520. BEOL resistor 510B is fabricated on the BEOL layer. In one implementation similar to the one shown in FIG. 2, the BEOL resistor layer (e.g., BEOL resistor layer 263 in FIG. 2) is between BEOL metal layers M4 (e.g., M4 270 in FIG. 2) and M3 (e.g., M3 260 in FIG. 2). BEOL resistor 510B can be fabricated on BEOL resistor layer 263. Capacitor 520 is fabricated on at least two metal layers underneath the BEOL layer. In one implementation similar to the one shown in FIG. 2, capacitor 520 can be fabricated on any two of the metal layers below the BEOL resistor layer 263, namely, M3 260, M2 250, M1 240, and/or M0 230. For example, capacitor 520 can include a first plate and a second plate, where the first plate can be fabricated on M3 260 and the second plate on M0 230. In another example, capacitor 520 can include two sets of fingers, where each set of fingers can be fabricated on a distinct metal layer underneath the BEOL resistor layer 263. In essence, capacitor 520 can be placed substantially underneath BEOL resistor 510B to save layout area. In some implementations, capacitor 520 and BEOL resistor 510B can be arranged into a physical stack.

In contrast to layout 550, the area occupied by layout 580 is significantly smaller because at least part of BEOL resistor 510B can be placed over capacitor 520, substantially forming a stack. It should be appreciated that capacitor 520 and BEOL resistor 510B are well suited for being placed in a stack because capacitor 520 and resistor 510B do not conduct any active current in the LDO circuit 500 and thus, self-heating is limited. Furthermore, routing coupling BEOL resistor 510B and capacitor 520 can be shorter than routing coupling MOL resistor 510A and capacitor 520 in FIG. 5B because the routing coupling BEOL resistor 510B and capacitor 520 can go through vias and metal layers between BEOL resistor layer and metal layers on which capacitor 520 resides in a direction substantially normal to the planar surface of silicon substrate.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A semiconductor circuit, comprising:
a resistor residing on a back end of line (BEOL) resistor layer;
a plurality of multi-level metal wires and interlevel metal vias coupling the BEOL resistor layer to one or more metal layers underneath the BEOL resistor layer; and
a diode residing on a silicon substrate underneath the one or more metal layers, wherein a planar surface of the diode and a planar surface of the resistor at least partially overlap with each other, and the diode and the resistor are coupled to each other through the plurality of multi-level metal wires and interlevel metal vias.

2. The semiconductor circuit of claim 1, further comprising an output driver and an electrostatic discharge (ESD) protection circuit coupled to an output of the output driver, wherein the diode is configured as part of the ESD protection circuit and the resistor is configured as part of the output driver.

3. The semiconductor circuit of claim 1, further comprising:
routing to couple the resistor to the diode, wherein the routing passes through the plurality of multi-level metal wires and interlevel metal vias.

4. The semiconductor circuit of claim 1, wherein the resistor and the diode are configured as part of a bandgap reference circuit.

5. The semiconductor circuit of claim 1, further comprising a first BEOL metal layer and a second BEOL metal layer, wherein the BEOL resistor layer is located between the first BEOL metal layer and the second BEOL metal layer.

6. The semiconductor circuit of claim 5, wherein the planar surface of the resistor, the planar surface of the diode, a planar surface of the silicon substrate, a planar surface of the first BEOL metal layer, and a planar surface of the second BEOL metal layer are substantially parallel to each other.

7. The semiconductor circuit of claim 6, wherein the plurality of interlevel metal vias extend in a direction normal to the first and second BEOL metal layers.

8. The semiconductor circuit of claim 7, wherein the plurality of interlevel metal vias locate above the silicon substrate.

9. The semiconductor circuit of claim 5, wherein the first BEOL metal layer is a Metal 4 (M4) layer and the second BEOL metal layer is a Metal 3 (M3) layer.

10. A semiconductor circuit, comprising:
a resistor residing on a back end of line (BEOL) resistor layer; and
a capacitor having a first plate and a second plate, the first plate residing on a first metal layer and the second plate residing on a second metal layer, wherein both the first and the second metal layers are located between a silicon substrate and the BEOL metal layer, wherein the resistor and the capacitor are arranged in a physical stack.

11. The semiconductor circuit of claim 10, wherein a planar surface of the resistor, a planar surface of the first plate of the capacitor, and a planar surface of the second plate of the capacitor are substantially parallel to each other.

12. The semiconductor circuit of claim 11, wherein the planar surface of the resistor, the planar surface of the first plate of the capacitor, and the planar surface of the second plate of the capacitor at least partially overlap with each other.

13. The semiconductor circuit of claim 10, further comprising:
routing to couple the resistor to the capacitor, wherein at least a portion of the routing extends in a direction substantially normal to a planar surface of the silicon substrate.

14. The semiconductor circuit of claim 10, wherein the resistor and the capacitor are coupled to each other in series between an output of a low drop out regulator (LDO) and ground.

15. An input/output (I/O), comprising:
an output driver having a resistor residing on a back end of line (BEOL) resistor layer; and
an electrostatic discharge (ESD) protection circuit having a diode residing on a silicon substrate underneath the BEOL resistor layer, wherein the resistor and the diode are arranged in a physical stack that extends in a direction normal to a planar surface of the silicon substrate.

16. The I/O of claim 15, further comprising:
routing to couple the resistor to the diode, wherein at least a portion of the routing extends in a direction substantially normal to the planar surface of the silicon substrate.

17. The I/O of claim 16, further comprising:
a first BEOL metal layer having a planar surface substantially parallel to the planar surface of the silicon substrate; and
a second BEOL metal layer having a planar surface substantially parallel to the planar surface of the silicon substrate, wherein the BEOL resistor layer locates between the first BEOL metal layer and the second BEOL metal layer.

18. The I/O of claim 17, further comprising:
a first interlevel metal via to couple a top planar surface of the BEOL resistor layer to a bottom planar surface of the first BEOL metal layer; and
a second interlevel metal via to couple the bottom planar surface of the first BEOL metal layer to a top planar surface of the second BEOL metal layer.

19. The I/O of claim 18, wherein the routing passes through the first interlevel metal via and the second interlevel metal via.

20. The I/O of claim 17, wherein the first BEOL metal layer is a Metal 4 (M4) layer and the second BEOL metal layer is a Metal 3 (M3) layer.
